(19) United States
(12) Patent Application Publication
(10) Pub. No.: US 2026/0334302 A1
(43) Pub. Date: Oct. 22, 2026

(54) METHOD FOR MANUFACTURING SEMICONDUCTOR DEVICE

(71) Applicant: Resonac Corporation, Minato-ku, Tokyo (JP)

(72) Inventors: Tadashi OKUDA, Tokyo (JP); Shizu FUKUZUMI, Tokyo (JP); Yuta FUJITA, Tokyo (JP); Kazuyuki MITSUKURA, Tokyo (JP); Yuki IMAZU, Tokyo (JP)

(21) Appl. No.: 19/475,422

(22) PCT Filed: May 24, 2023
(86) PCT No.: PCT/JP2023/019348

§ 371 Date: Oct. 15, 2025

(51) Int. Cl. H10W 80/00; H10P 58/00; H10W 72/00; H10W 72/90; H10W 90/00; H10W 90/28

(52) U.S. Cl. CPC H10W 80/327; H10P 58/00; H10W 72/0198; H10W 72/953; H10W 80/041; H10W 80/102; H10W 80/312; H10W 80/334; H10W 90/28; H10W 90/792

(57) ABSTRACT

A method for manufacturing a semiconductor device (semiconductor chip stack) comprising: irradiating at least one of a first insulating resin film of a first semiconductor member or a second insulating resin film of a second semiconductor member with ultraviolet light; and bonding the first semiconductor member and the second semiconductor member by hybrid bonding in which the first insulating resin film and the second insulating resin film are bonded. Even at a low temperature of about 200° C., the insulating resin films can be favorably bonded to each other.

### TECHNICAL FIELD

The present disclosure relates to a method for manufacturing a semiconductor device.

### BACKGROUND ART

As a three-dimensional integration technology for semiconductor chips, a hybrid bonding technology is sometimes applied, in which electrodes are bonded to each other and insulating films around the electrodes are also bonded to each other. The insulating film for hybrid bonding is often a silica film, but the use of an insulating resin film formed from a photosensitive resin is also being considered (for example, Patent Literature 1). Since an insulating resin film is less susceptible to the influence of foreign matter and the like compared to a silica film, it is expected that the adoption of an insulating resin film will improve the yield.

### CITATION LIST

### Patent Literature

Patent Literature 1: Japanese Unexamined Patent Publication No. 2012-069585

### SUMMARY OF INVENTION

### Technical Problem

The present disclosure relates to a method for bonding insulating resin films to each other by heating at a lower temperature when manufacturing a semiconductor device by hybrid bonding that includes bonding insulating resin films to each other.

### Solution to Problem

The present disclosure includes the following.
[1]A method for manufacturing a semiconductor device comprising:
   preparing a first semiconductor member having a first semiconductor substrate and a first bonding layer disposed on the first semiconductor substrate, the first bonding layer comprising a first electrode and a first insulating resin film, the first insulating resin film having an opening, and the first electrode being disposed within the opening;
   preparing a second semiconductor member having a second semiconductor substrate and a second bonding layer disposed on the second semiconductor substrate, the second bonding layer comprising a second electrode and a second insulating resin film, the second insulating resin film having an opening, and the second electrode being disposed within the opening;
   irradiating at least one of the first insulating resin film or the second insulating resin film with ultraviolet light; and
   bonding the first semiconductor member and the second semiconductor member by hybrid bonding in which the first electrode and the second electrode are bonded and the first insulating resin film and the second insulating resin film are bonded.
[2] The method according to [1], wherein bonding the first semiconductor member and the second semiconductor member comprises press-bonding the first semiconductor member and the second semiconductor member while heating them at a temperature of 180° C. or more and 250° C. or less, thereby bonding the first insulating resin film and the second insulating resin film.
[3] The method according to [1] or [2],
   wherein the first semiconductor substrate is a semiconductor wafer, the second semiconductor substrate is a semiconductor chip, a plurality of the second semiconductor members are bonded to the one first semiconductor member,
   and the method further comprises dividing the first semiconductor member bonded to the second semiconductor members, thereby forming a semiconductor chip stack comprising the first semiconductor member having the first semiconductor substrate singulated into a semiconductor chip, and the second semiconductor members.
[4] The method according to any one of [1] to [3], wherein the first insulating resin film and the second insulating resin film comprise a resin having an imide group.
[5] The method according to [4], wherein the resin having an imide group is a polyimide resin, a polyamide-imide resin, a bismaleimide resin, or a combination thereof.
[6] The method according to [4], wherein the resin containing an imide group is a resin having a constitutional unit having an imide group and a polysiloxane bonded to the constitutional unit.
[7] The method according to any one of [1] to [3], wherein the first insulating resin film and the second insulating resin film comprise a polybenzoxazole resin.
[8] The method according to any one of [1] to [3], wherein the first insulating resin film and the second insulating resin film comprise a benzocyclobutene resin.

### Advantageous Effects of Invention

When manufacturing a semiconductor device by hybrid bonding that includes bonding insulating resin films to each other, it is possible to bond the insulating resin films to each other by heating at a lower temperature. By bonding the insulating resin films to each other by heating at a low temperature, damage to the semiconductor members due to high heat can be easily avoided. Furthermore, the generation of outgas from the insulating resin film can also be suppressed.

### BRIEF DESCRIPTION OF DRAWINGS

FIG. 1 is a process diagram showing an example of a method for manufacturing a semiconductor device.

FIG. 2 is a process diagram showing an example of a method for manufacturing a semiconductor device.

FIG. 3 is a process diagram showing an example of a method for manufacturing a semiconductor device.

### DESCRIPTION OF EMBODIMENTS

The present invention is not limited to the following examples.

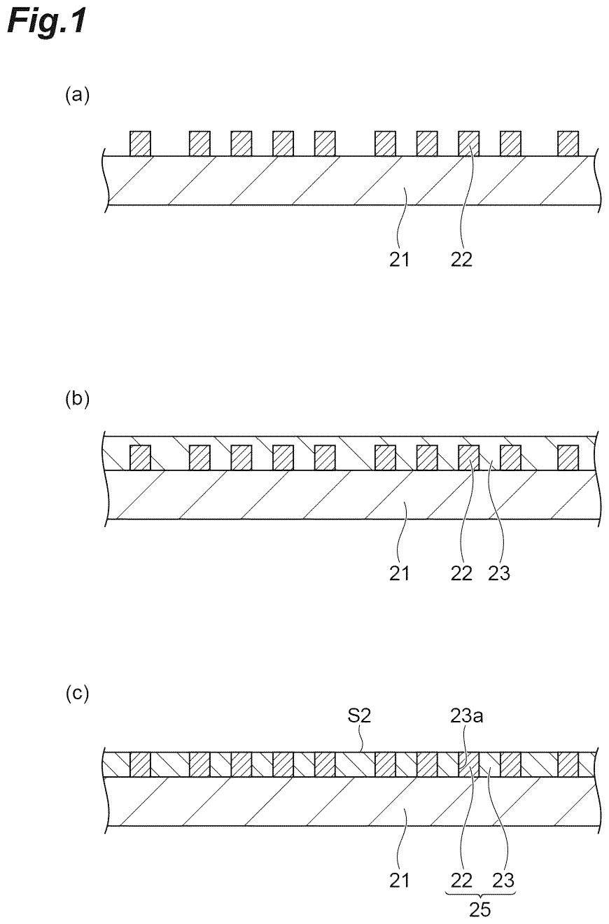

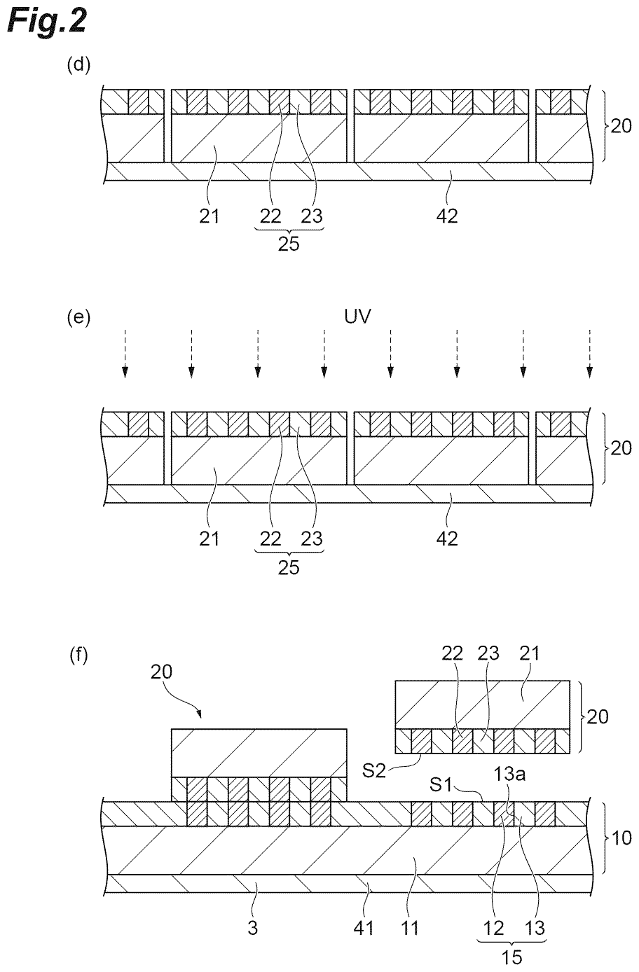

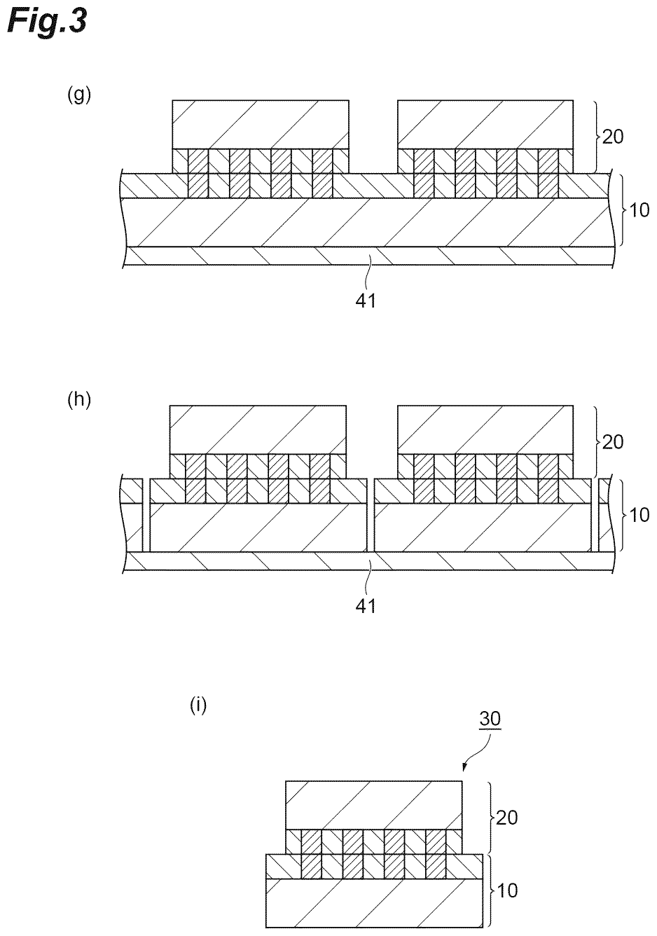

FIG. 1, FIG. 2, and FIG. 3 are process diagrams showing an example of a method for manufacturing a semiconductor device by the method according to the present disclosure. The method shown in FIGS. 1 to 3 comprises: preparing a first semiconductor member 10 having a first semiconductor substrate 11 and a first bonding layer 15 disposed on the first semiconductor substrate 11, wherein the first bonding layer 15 comprises a first electrode 12 and a first insulating resin film 13; preparing a second semiconductor member 20 having a second semiconductor substrate 21 and a second bonding layer 25 disposed on the second semiconductor substrate 21, wherein the second bonding layer 25 comprises a second electrode 22 and a second insulating resin film 23; irradiating at least one of the first insulating resin film 13 or the second insulating resin film 23 with ultraviolet light UV; and bonding the first semiconductor member 10 and the second semiconductor member 20 by hybrid bonding.

In the example shown in FIGS. 1 to 3, a first semiconductor member 10 having a first semiconductor substrate 11, which is a semiconductor wafer, and a second semiconductor member 20 having a second semiconductor substrate 21, which is a semiconductor chip, are bonded by hybrid bonding. A plurality of second semiconductor members 20 are bonded to one first semiconductor member 10, and subsequently, the first semiconductor member 10 bonded to the second semiconductor members 20 is divided. As a result, a semiconductor chip stack 30 (semiconductor device) is formed, comprising the first semiconductor member 10 having the first semiconductor substrate 11 singulated into a semiconductor chip, and the second semiconductor member 20. However, the combination of the first semiconductor member and the second semiconductor member to be bonded is not limited to this and can be changed as appropriate.

Preparing the second semiconductor member 20 includes, for example: providing a plurality of second electrodes 22 on one main surface of the second semiconductor substrate 21 as shown in FIG. 1(a); providing a second insulating resin film 23 covering the second electrodes 22 as shown in FIG. 1(b); forming an opening 23a that exposes the second electrodes 22 by removing a part of the second insulating resin film 23 from the side opposite to the second semiconductor substrate 21, as shown in FIG. 1(c); and dividing the second semiconductor substrate 21 and the second insulating resin film 23 as shown in FIG. 2(d), thereby forming the second semiconductor member 20 having the second semiconductor substrate 21, which is a singulated semiconductor chip, the second electrodes 22, and the second insulating resin film 23.

The second semiconductor substrate 21 before being singulated into semiconductor chips can be a semiconductor wafer. The diameter of the semiconductor wafer (the second semiconductor substrate) may be, for example, 150 mm or more and 300 mm or less. The thickness of the semiconductor wafer (the second semiconductor substrate) may be, for example, 40 μm or more and 1000 μm or less.

The second electrode 22 can be, for example, a conductive material containing copper. The width (maximum width) of the second electrode 22 may be, for example, 1 μm or more and 13 μm or less. The height of the second electrode 22 may be, for example, 1 μm or more and 90 μm or less. A through-electrode penetrating the second semiconductor substrate 21 may be provided. The second electrode 22 can be formed by a conventional method using plating or the like.

The second insulating resin film 23 can be, for example, a film comprising a resin containing an imide group, a polybenzoxazole resin, a benzocyclobutene resin, or a combination thereof. The first insulating resin film 13 can also be a film comprising a resin containing an imide group, a polybenzoxazole resin, a benzocyclobutene resin, or a combination thereof.

The resin containing an imide group, which constitutes the first insulating resin film 13 and the second insulating resin film 23, may be a polyimide resin, a polyamide-imide resin, or a bismaleimide resin. The polyimide resin can be, for example, a polymer comprising a constitutional unit (imide unit) represented by the following formula (1A). The polyamide-imide resin can be a polymer comprising a constitutional unit (imide unit) represented by the following formula (1B) or (1C). Alternatively, the resin containing an imide group may be a resin having an imide unit represented by formula (1A), (1B), or (1C), and a linear, branched, or cage-like polysiloxane bonded to the imide unit.

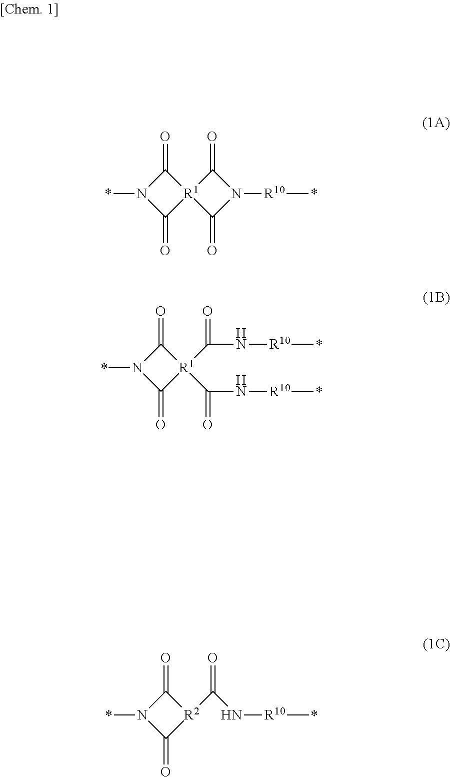

In formulas (1A) to (1C), R¹ represents a tetravalent organic group, R² represents a trivalent organic group, R¹⁰ represents a divalent organic group, and * represents a point of attachment.

R¹ can be a group containing an aromatic group, for example, R¹ may be a group obtained by removing four hydrogen atoms from a compound represented by the following formula (11), (12), or (13). R² can be a group containing an aromatic group, for example, R² may be a group obtained by removing three hydrogen atoms from a compound represented by the following formula (11), (12), or (13). In formula (13), X represents a direct bond, a methanediyl group, a propane-2,2-diyl group, a 1,1,1,3,3,3-hexafluoropropane-2,2-diyl group, a carbonyl group, a sulfonyl group, a thio group, a carbonyloxy group, an oxy group, a fluorene-9,9-diyl group, or an amide group.

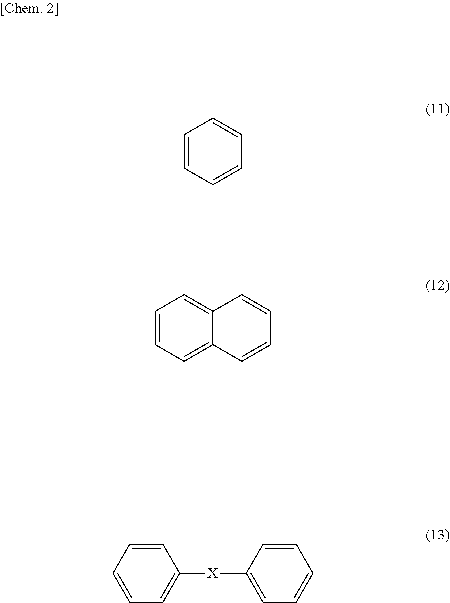

R¹⁰ in formulas (1A) to (1C) may be a group containing an optionally substituted alkylene group, a group containing an optionally substituted aromatic group, a group containing an optionally substituted cycloaliphatic group, or a group containing a combination thereof. The aromatic group may be a group obtained by removing two hydrogen atoms from a compound represented by formula (11), (12), or (13).

The insulating resin film comprising a resin containing an imide group can be formed, for example, by a method comprising: applying a resin varnish containing a resin precursor onto the first semiconductor substrate or the second semiconductor substrate; and heating the coating film to form an insulating resin film comprising a resin containing an imide group. When forming an insulating resin film comprising a polymer containing imide units (a polyimide resin or a polyamide-imide resin), the resin precursor can be a polyamic acid having a constitutional unit corresponding to the imide unit. By heating the coating film, a curing reaction including an imidization reaction proceeds, thereby forming an insulating resin film comprising a polyimide resin or a polyamide-imide resin. When forming an insulating resin film comprising a resin containing a polysiloxane bonded to an imide unit, the resin precursor can comprise a combination of a polycarboxylic acid compound corresponding to the imide unit and a polysiloxane substituted with a substituent having an amino group. The polycarboxylic acid compound may include an anhydride or a carboxylic acid ester. An insulating resin film comprising a resin having an imide group is formed by a curing reaction including the reaction between the amino group of the substituent bonded to the polysiloxane and the polycarboxylic acid compound, and an imidization reaction.

An insulating resin film comprising a polybenzoxazole resin can be formed, for example, by a method comprising: applying a resin varnish containing a resin precursor onto the first semiconductor substrate or the second semiconductor substrate; and heating the coating film to allow a curing reaction including a reaction to form a benzoxazole group to proceed, thereby forming an insulating resin film comprising a polybenzoxazole resin.

A part of the second insulating resin film 23 formed to cover the entire second electrodes 22 is removed so that the second electrodes 22 are exposed. Thereby, a second bonding layer 25 is formed, having the second insulating resin film 23 with a plurality of openings 23a, and the second electrodes 22 provided within the respective openings 23a. For example, a part of the second insulating resin film 23 is removed by chemical mechanical polishing (CMP). The second bonding surface S2, which is the surface of the second bonding layer 25 on the side opposite to the second semiconductor substrate 21, may be a flat surface, or a protrusion or a recess may be formed at the position of the second electrode 22.

After the second insulating resin film 23 is formed, as shown in FIG. 2(d), the second semiconductor substrate 21 is fixed to a dicing tape 42, and in that state, the second semiconductor substrate 21 is divided together with the second insulating resin film 23 by dicing. By the division, a second semiconductor member 20 is formed on the dicing tape 42, having the second semiconductor substrate 21, which is a semiconductor chip.

Prior to bonding by hybrid bonding, as shown in FIG. 2(e), the second insulating resin film 23 is irradiated with ultraviolet light UV The insulating resin film irradiated with ultraviolet light can be favorably bonded with another insulating resin film at a relatively low temperature. It is considered that polar groups are formed on the surface of the second insulating resin film 23 by the irradiation with ultraviolet light, and this contributes to the improvement of bondability at low temperatures.

The integrated light quantity of the ultraviolet light with which the second insulating resin film 23 is irradiated can be adjusted to obtain appropriate bonding, in consideration of conditions such as the heating temperature adopted for hybrid bonding. For example, the integrated light quantity of the ultraviolet light with which the second insulating resin film 23 is irradiated may be 500 mJ/cm² or more and 20000 mJ/cm² or less. The integrated light quantity of the ultraviolet light with which the second insulating resin film 23 is irradiated may be 600 mL/cm² or more, 700 mL/cm² or more, 800 mL/cm² or more, 900 mL/cm² or more, 1000 mL/cm² or more, 1100 mL/cm² or more, 1200 mL/cm² or more, 1300 mL/cm² or more, 1400 mL/cm² or more, 1500 mL/cm² or more, 1600 mL/cm² or more, 1700 mL/cm² or more, or 1800 mL/cm² or more, and may be 19000 mJ/cm² or less, 18000 mJ/cm² or less, 17000 mJ/cm² or less, 16000 mJ/cm² or less, 15000 mJ/cm² or less, 14000 mJ/cm² or less, 13000 mJ/cm² or less, 12000 mJ/cm² or less, 11000 mJ/cm² or less, 10000 mJ/cm² or less, or 9000 mJ/cm² or less.

The ultraviolet light is irradiated onto the second insulating resin film 23 before the bonding of the first semiconductor member 10 and the second semiconductor member 20. The second insulating resin film 23 may be irradiated with ultraviolet light before being divided by dicing.

The first semiconductor member 10 shown in FIG. 2(f) can also be prepared by a method similar to the method exemplified above for the preparation of the second semiconductor member 20. The first semiconductor member 10 has a first bonding layer 15 having a first insulating resin film 13 with a plurality of openings 13a, and first electrodes 12 provided within the respective openings 13a.

The diameter of the semiconductor wafer as the first semiconductor substrate 11 may be, for example, 150 mm or more and 300 mm or less. The thickness of the semiconductor wafer as the first semiconductor substrate 11 may be, for example, 40 μm or more and 1000 μm or less.

The first electrode 12 can be, for example, a conductive material containing copper. The width (maximum width) of the first electrode 12 may be, for example, 1 μm or more and 13 μm or less. The height of the first electrode 12 may be, for example, 1 μm or more and 90 μm or less. A through-electrode penetrating the first semiconductor substrate 11 may be provided. The first bonding surface S1, which is the surface of the first bonding layer 15 on the side opposite to the first semiconductor substrate 11, may be a flat surface, or a protrusion or a recess may be formed at the position of the first electrode 12.

Before the bonding of the first semiconductor member 10 and the second semiconductor member 20, the first insulating resin film 13 may be irradiated with ultraviolet light. Both the first insulating resin film 13 and the second insulating resin film 23 may be irradiated with ultraviolet light, or only one of the first insulating resin film 13 or the second insulating resin film 23 may be irradiated with ultraviolet light.

In the example of FIGS. 2 and 3, a plurality of second semiconductor members 20 picked up from the dicing tape 42 are bonded to one first semiconductor member 10 fixed on the dicing tape 41 by hybrid bonding. The second semiconductor member 20 is placed at a position on the second bonding surface S2 such that the first electrode 12 and the second electrode 22 are disposed to face each other, with the first bonding surface S1 and the second bonding surface S2 in contact. In that state, the first semiconductor member 10 and the second semiconductor member 20 are bonded by press-bonding them while heating the first semiconductor member 10 and the second semiconductor member 20 to a predetermined heating temperature (FIG. 3(g)).

The step of bonding the first semiconductor member 10 and the second semiconductor member 20 may include: a preliminary bonding in which the first semiconductor member 10 and the second semiconductor member 20 are press-bonded while being heated, thereby bonding the first insulating resin film 13 and the second insulating resin film 23; and an annealing in which the entire stack having the first semiconductor member and the plurality of second semiconductor members 20 is heated and pressurized, thereby bonding the first electrode 12 and the second electrode 22. In the case of a method including preliminary bonding and annealing, the first insulating resin film 13 and the second insulating resin film 23 are mainly bonded at the preliminary bonding stage, and the first electrode 12 and the second electrode 22 are mainly metal-bonded at the annealing stage. However, the first electrode 12 and the second electrode 22 can be bonded to some extent at the preliminary bonding stage. Also, the first insulating resin film 13 and the second insulating resin film 23 can be bonded more strongly at the annealing stage.

If the first insulating resin film 13, the second insulating resin film 23, or both are irradiated with ultraviolet light before hybrid bonding, the insulating resin films can be favorably bonded to each other even if the heating temperature is low. The heating temperature for preliminary bonding may be the same as or lower than the temperature for annealing for bonding the electrodes. The heating temperature for bonding the first insulating resin film 13 and the second insulating resin film 23 (preliminary bonding) may be, for example, 180° C. or more and 250° C. or less. This heating temperature may be 240° C. or less, 230° C. or less, or 220° C. or less, and may be 190° C. or more, or 200° C. or more. The pressure for preliminary bonding may be, for example, 0.5 MPa or more and 10 MPa or less. The time for heating and pressurizing for preliminary bonding may be, for example, 3 seconds or more and 120 minutes or less.

In annealing, the stack having the first semiconductor member 10 and the plurality of second semiconductor members 20 is heated and pressurized, for example, in a pressurized oven. The heating temperature for annealing is adjusted so that metal bonding is formed, and may be, for example, 190° C. or more and 400° C. or less. The heating temperature for annealing may be 200° C. or more, 210° C. or more, 220° C. or more, 230° C. or more, 240° C. or more, 250° C. or more, or 260° C. or more, and may be 390° C. or less, 380° C. or less, 370° C. or less, 360° C. or less, or 350° C. or less. The pressure in annealing may be, for example, 0.1 MPa or more and MPa or less. The time for heating and pressurizing for annealing may be, for example, 10 minutes or more and 120 minutes or less.

When the first electrode 12 and the second electrode 22 are metal-bonded at a relatively low temperature, the first electrode 12 and the second electrode 22 can be sufficiently bonded at the temperature of the preliminary bonding. In that case, the first insulating resin film 13 and the second insulating resin film 23 may be bonded, and the first electrode 12 and the second electrode 22 may be bonded, by a one-step press-bonding.

After the first semiconductor member 10 and the second semiconductor member 20 are bonded, as shown in FIG. 3(h), the first semiconductor member 10 bonded to the second semiconductor member is divided by dicing. As a result, a semiconductor chip stack 30 is formed on the dicing tape 41, comprising the first semiconductor member 10 having the first semiconductor substrate singulated into a semiconductor chip, and the second semiconductor member 20. Thereafter, as shown in FIG. 3(i), the semiconductor chip stack 30 (semiconductor device) is picked up from the dicing tape 41.

### EXAMPLES

The present invention is not limited to the following test examples.

### (Test 1)

A test semiconductor chip stack in which a lower semiconductor member and an upper semiconductor member were bonded was produced by the following procedure, and the shear peel strength of the bonding surface was measured.

First, a large number of copper pillars (electrodes) of 10 μm square and 4 μm height were formed on a silicon wafer for an upper semiconductor member. A resin varnish containing polyamic acid was applied onto the silicon wafer on which the copper pillars were provided, and the coating film was cured by heating at 250° C. to form an insulating resin film containing polyimide resin (PI) and covering the copper pillars. The insulating resin film was polished by a CMP method to form a bonding layer of the upper semiconductor member having exposed copper pillars and an insulating resin film (thickness: 3.9 μm) filling the periphery thereof. The upper semiconductor member was fixed on a dicing tape, and subsequently, an upper semiconductor member having a singulated semiconductor chip and a bonding layer was formed by dicing using a blade dicer. The singulated semiconductor chip had a size of 4 mm×4 mm. The entire surface of the insulating resin film on the semiconductor chip was irradiated with ultraviolet light. The integrated light quantity of the ultraviolet light was adjusted by the exposure time.

On a silicon wafer for a lower semiconductor member, copper pillars and an insulating resin film filling the periphery thereof were formed in the same manner as for the lower semiconductor member to obtain a lower semiconductor member having a silicon wafer and a bonding layer. The upper semiconductor member after the insulating resin film was irradiated with ultraviolet light was picked up from the dicing tape, and after aligning the copper pillars of the upper semiconductor member and the copper pillars of the lower semiconductor member, the upper semiconductor member was press-bonded to the lower semiconductor member in a direction in which the copper pillars contact each other, thereby preliminarily bonding the lower semiconductor member and the upper semiconductor member. During this preliminary bonding, the lower semiconductor member and the upper semiconductor member were heated to 210° C. After the preliminary bonding, the formed preliminarily bonded body was subjected to annealing by heating for 120 minutes at a predetermined annealing temperature (210-300° C.) in a pressurized oven in a nitrogen atmosphere, thereby metal-bonding the copper pillars to each other.

After annealing, the silicon wafer of the lower semiconductor member was singulated into semiconductor chips by dicing using a blade dicer on a dicing tape. The singulated semiconductor chip had a size of 8 mm×8 mm, and one upper semiconductor member was bonded to one lower semiconductor member by hybrid bonding. The test semiconductor chip stack composed of the lower semiconductor member and the upper semiconductor member was picked up from the dicing tape.

The test semiconductor chip stack was fixed on a stage at 260° C., and a shear stress was applied to the upper semiconductor member by moving a jig pressed against the side surface of the upper semiconductor member at a speed of 20 μm/min. The shear strength of the bonding surface by hybrid bonding was determined from the stress at the time when the upper semiconductor member peeled off from the lower semiconductor member.

The manufacturing conditions and shear strength of the test semiconductor chip stacks are shown in Table 1. #1 to #3 are examples of test semiconductor chip stacks produced without exposing the insulating resin film before preliminary bonding. The test semiconductor chip stacks of #4 to #7, in which the insulating resin film was irradiated with ultraviolet light before preliminary bonding, showed higher shear strength compared to the semiconductor chip stack of #1 without ultraviolet irradiation, and also showed higher shear strength compared to the semiconductor chip stack of #3 which was annealed at a high temperature of 300° C. without ultraviolet irradiation.

TABLE 1

| | | UV | Preliminary | | |
|---|---|---|---|---|---|
| | Insulating | integrated | bonding | Annealing | Shear |
| | resin | light quantity | temperature | temperature | strength |
| | film | [mJ/cm²] | [° C.] | [° C.] | [MPa] |
| #1 | PI | 0 | 210 | 210 | 26.8 |
| #2 | PI | 0 | 210 | 250 | 20.7 |
| #3 | PI | 0 | 210 | 300 | 27.1 |
| #4 | PI | 1800 | 210 | 210 | 29.5 |
| #5 | PI | 3600 | 210 | 210 | Over 30 |
| #6 | PI | 5400 | 210 | 210 | 29.5 |
| #7 | PI | 9000 | 210 | 210 | 29.1 |

A test semiconductor chip stack was produced in the same manner as in Test 1, except that an insulating resin film containing polybenzoxazole resin (PBO) was formed instead of the insulating resin film containing polyimide resin, and its shear strength was measured. The manufacturing conditions and shear strength of the semiconductor chip stack are shown in Table 2. Also in the case of the insulating resin film containing polybenzoxazole resin, it was confirmed that the shear strength increased even at a low preliminary bonding temperature by ultraviolet irradiation before preliminary bonding.

TABLE 2

| | | UV | Pre- | | |
|---|---|---|---|---|---|
| | In- | integrated | liminary | | |
| | sulating | light | bonding | Annealing | Shear |
| | resin | quantity | temperature | temperature | strength |
| | film | [mJ/cm²] | [° C.] | [° C.] | [MPa] |
| #8 | PBO | 0 | 210 | 210 | 3.92 |
| #9 | PBO | 1800 | 210 | 210 | 6.59 |
| #10 | PBO | 3600 | 210 | 210 | 7.03 |
| #11 | PBO | 5400 | 210 | 210 | 6.53 |
| #12 | PBO | 9000 | 210 | 210 | 7.86 |

### REFERENCE SIGNS LIST

10 . . . first semiconductor member, 11 . . . first semiconductor substrate, 12 . . . first electrode, 13 . . . first insulating resin film, 13a . . . opening, 20 . . . second semiconductor member, 21 . . . second semiconductor substrate, 22 . . . second electrode, 23 . . . second insulating resin film, 23a . . . opening, 30 . . . semiconductor chip stack (semiconductor device), UV . . . ultraviolet light.

1. A method for manufacturing a semiconductor device comprising:
preparing a first semiconductor member having a first semiconductor substrate and a first bonding layer disposed on the first semiconductor substrate, the first bonding layer comprising a first electrode and a first insulating resin film, the first insulating resin film having an opening, and the first electrode being disposed within the opening;
preparing a second semiconductor member having a second semiconductor substrate and a second bonding layer disposed on the second semiconductor substrate, the second bonding layer comprising a second electrode and a second insulating resin film, the second insulating resin film having an opening, and the second electrode being disposed within the opening;
irradiating at least one of the first insulating resin film or the second insulating resin film with ultraviolet light; and
bonding the first semiconductor member and the second semiconductor member by hybrid bonding in which the first electrode and the second electrode are bonded and the first insulating resin film and the second insulating resin film are bonded.

2. The method according to claim 1, wherein bonding the first semiconductor member and the second semiconductor member comprises press-bonding the first semiconductor member and the second semiconductor member while heating them at a temperature of 180° C. or more and 250° C. or less, thereby bonding the first insulating resin film and the second insulating resin film.

3. The method according to claim 1,
wherein the first semiconductor substrate is a semiconductor wafer, the second semiconductor substrate is a semiconductor chip, a plurality of the second semiconductor members are bonded to the one first semiconductor member,
and the method further comprises dividing the first semiconductor member bonded to the second semiconductor members, thereby forming a semiconductor chip stack comprising the first semiconductor member having the first semiconductor substrate singulated into a semiconductor chip, and the second semiconductor members.

4. The method according to claim 1, wherein the first insulating resin film and the second insulating resin film comprise a resin having an imide group.

5. The method according to claim 4, wherein the resin having an imide group is a polyimide resin, a polyamide-imide resin, a bismaleimide resin, or a combination thereof.

6. The method according to claim 4, wherein the resin having an imide group is a resin having a constitutional unit containing an imide group and a polysiloxane bonded to the constitutional unit.

7. The method according to claim 1, wherein the first insulating resin film and the second insulating resin film comprise a polybenzoxazole resin.

8. The method according to claim 1, wherein the first insulating resin film and the second insulating resin film comprise a benzocyclobutene resin.
